(19) United States
(12) Patent Application Publication
(10) Pub. No.: US 2025/0380606 A1
(43) Pub. Date: Dec. 11, 2025

(54) Display Module and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyangn District, Beijing (CN)

(72) Inventors: Shengxing Zhang, Beijing (CN); Jiafan Shi, Beijing (CN); Chao Yang, Beijing (CN); Chuandong Liao, Beijing (CN); Wenliang Liu, Beijing (CN); Wanxu Gao, Beijing (CN); Pan Hu, Beijing (CN)

(21) Appl. No.: 18/688,130

(22) PCT Filed: Sep. 29, 2022
(86) PCT No.: PCT/CN2022/122859

§ 371 Date: Feb. 29, 2024

(51) Int. Cl. H10K 77/10; G06F 1/16; H10K 59/38; H10K 59/80; H10K 102/00

(52) U.S. Cl. CPC H10K 77/111; G06F 1/1652; H10K 59/873; H10K 59/878; H10K 59/8792; H10K 59/8793; H10K 59/38; H10K 2102/351

(57) ABSTRACT

A display module is disclosed. The display module includes a flexible display panel, a polarizer, a transparent support layer and a mirror structure layer. The polarizer is located on a display surface of the flexible display panel. The transparent support layer is located on a side of the polarizer away from the flexible display panel. The mirror structure layer is located on a side of the transparent support layer away from the polarizer. An elastic modulus of the transparent support layer is greater than an elastic modulus of the polarizer.

### CROSS-REFERENCE TO RELATED APPLICATION

This application is the United States national phase of International Patent Application No. PCT/CN2022/122859, filed Sep. 29, 2022, the disclosure of which is hereby incorporated by reference in its entirety.

### BACKGROUND OF THE INVENTION

### Field of the Invention

The present disclosure relates to the field of display technologies, and in particular, to a display module and a display apparatus.

### Description of Related Art

With rapid development of the display technology, display apparatuses with multi functions continue to emerge. The display apparatuses include a mirror display apparatus that implement display and mirror functions. Mirror display means that users may see a display picture from the mirror's display while using the mirror, which may meet people's various needs.

### SUMMARY OF THE INVENTION

In an aspect, a display module is provided. The display module includes a flexible display panel, a polarizer, a transparent support layer and a mirror structure layer. The polarizer is located on a display surface of the flexible display panel. The transparent support layer is located on a side of the polarizer away from the flexible display panel. The mirror structure layer is located on a side of the transparent support layer away from the polarizer. An elastic modulus of the transparent support layer is greater than an elastic modulus of the polarizer.

In some embodiments, the display module further includes a first adhesive layer and a second adhesive layer. The first adhesive layer is located between the transparent support layer and the polarizer. The second adhesive layer is located between the mirror structure layer and the transparent support layer. The elastic modulus of the transparent support layer is greater than an elastic modulus of the first adhesive layer.

In some embodiments, the display module has a display area and a peripheral area. The display module further includes a light-shielding layer located in the peripheral area and located between the first adhesive layer and the transparent support layer. The light-shielding layer is adjacent to the display area, and the light-shielding layer surrounds the display area.

In some embodiments, the light-shielding layer includes an ink layer.

In some embodiments, a thickness of the transparent support layer is greater than or equal to 20 μm.

In some embodiments, a thickness of the transparent support layer is less than or equal to 100 μm.

In some embodiments, a thickness of the transparent support layer is in a range of 30 μm to 70 μm, inclusive.

In some embodiments, the elastic modulus of the transparent support layer is in a range of 4 GPa to 200 GPa, inclusive.

In some embodiments, the elastic modulus of the transparent support layer is in a range of 30 GPa to 100 GPa, inclusive.

In some embodiments, the elastic modulus of the transparent support layer is in a range of 60 GPa to 80 GPa, inclusive.

In some embodiments, a transmittance of the transparent support layer is greater than or equal to 95%.

In some embodiments, a material of the transparent support layer includes at least one of inorganic glass, thermoplastic rubber, colorless polyimide or organic glass.

In some embodiments, the display module further includes a protective cover plate and a third adhesive layer. The protective cover plate located on a side of the mirror structure layer away from the transparent support layer. The third adhesive layer is located between the protective cover plate and the mirror structure layer. A material of the protective cover plate includes at least one of inorganic glass, thermoplastic rubber, colorless polyimide or organic glass.

In some embodiments, the display module further includes a hardened coating. The hardened coating is disposed on a surface of the mirror structure layer away from the transparent support layer.

In some embodiments, the display module further includes a heat dissipation film. The heat dissipation film is located on a back surface of the flexible display panel, and the back surface is a surface opposite to the display surface. The heat dissipation film includes a fourth adhesive layer, a buffer layer and a heat dissipation layer. The buffer layer is located on a side of the fourth adhesive layer away from the flexible display panel. The heat dissipation layer is located on a side of the buffer layer away from the fourth adhesive layer, and the heat dissipation layer includes a stainless steel layer and/or a carbon fiber layer.

In some embodiments, the display module has a bendable area, and at least a portion of the heat dissipation layer located in the bendable area is configured to have a hollow structure.

In some embodiments, the display module includes a scrollable display module or a foldable display module.

In some embodiments, the mirror structure layer includes at least one mirror orientation layer; and a direction of a transmission axis of the at least one mirror orientation layer is perpendicular to a direction of an absorption axis of the polarizer.

In some embodiments, the mirror structure layer includes a metal reflective layer.

In another aspect, a display apparatus is provided. The display apparatus includes the display module as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of a display module, in accordance with some embodiments;

FIG. 3 is a structural diagram of a display surface of a display module, in accordance with some embodiments;

FIG. 4 is a structural diagram of a display module, in accordance with some other embodiments;

FIG. 5 is a structural diagram of a display module, in accordance with yet other embodiments;

FIG. 6 is an electron microscope image of a display module, in accordance with some embodiments;

FIG. 7 is a structural diagram of a display module, in accordance with yet other embodiments;

FIG. 8 is a structural diagram of a display module, in accordance with yet other embodiments;

FIG. 9 is a structural diagram of a display module, in accordance with yet other embodiments;

FIG. 10 is a structural diagram of a display module, in accordance with yet other embodiments;

FIG. 11 is a structural diagram of a display module, in accordance with yet other embodiments;

FIG. 12 is a structural diagram of a display module, in accordance with yet other embodiments;

FIG. 13 is a structural diagram of a display module, in accordance with yet other embodiments;

FIG. 14 is a structural diagram of a display module, in accordance with yet other embodiments;

FIG. 15 is a structural diagram of a display module, in accordance with yet other embodiments;

FIG. 16 is a structural diagram of a display module, in accordance with yet other embodiments; and

FIG. 17 is a structural diagram of a display module, in accordance with yet other embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system).

For example, the term “perpendicular” includes absolute perpendicularity and approximate perpendicularity, and an acceptable range of deviation of the approximate perpendicularity may be a deviation within 5°; and the term “equal” includes absolute equality and approximate equality, and an acceptable range of deviation of the approximate equality may be a difference between two equals being less than or equal to any of 10%, 8% and 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

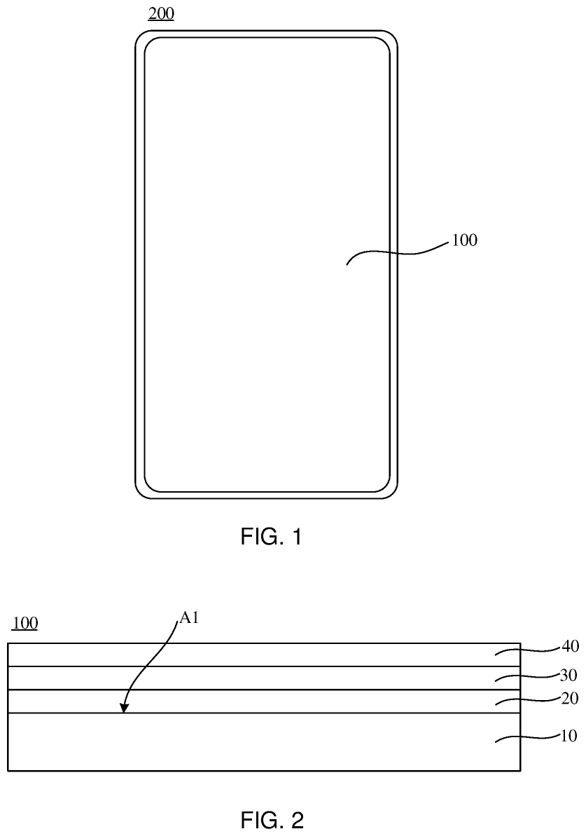

FIG. 1 is a structural diagram of a display apparatus in accordance with some embodiments.

As shown in FIG. 1, some embodiments of the present disclosure provide a display apparatus 200. The display apparatus 200 includes a display module 100.

For examples, the display apparatus 200 further includes a frame, a display driver integrated circuit (IC) and other electronic components.

For examples, the display apparatus may be an electroluminescent display apparatus or a photoluminescent display apparatus. In a case where the display apparatus is the electroluminescent display apparatus, the electroluminescent display apparatus may be an organic light-emitting diode (OLED) display apparatus or a quantum dot light-emitting diode (QLED) display apparatus. In a case where the display apparatus is the photoluminescent display apparatus, the photoluminescent display apparatus may be a quantum dot photoluminescent display apparatus. The display apparatus may also be a mini light-emitting diode (mini LED) display apparatus or a micro light-emitting diode (micro LED) display apparatus.

In a case where the display apparatus 200 is an OLED display apparatus, a QLED display apparatus, a mini LED display apparatus, or a micro LED display apparatus, in some embodiments, a display panel in the display apparatus 200 includes a light-emitting substrate, and the light-emitting substrate may realize image display.

For example, the display apparatus 200 may be any apparatus that displays images whether in motion (such as a video) or fixed (such as a still image), and regardless of text or image. More specifically, it is expected that the display apparatus in the described embodiments may be implemented in or associated with a variety of electronic devices. The variety of electronic devices may include (but are not limited to), for example, mobile telephones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

The OLED display apparatus will be described as an example below.

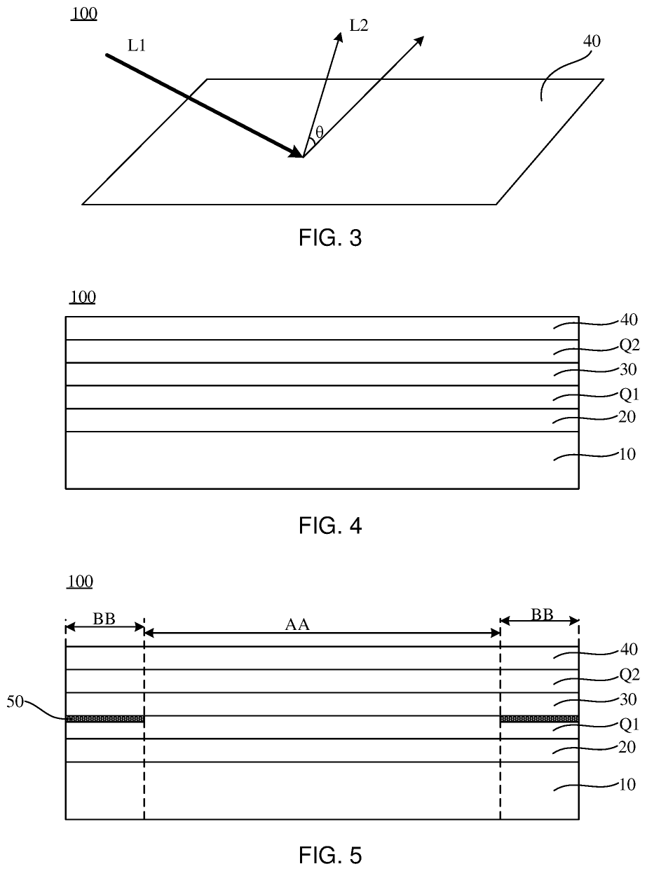

FIG. 2 is a structural diagram of a display module in accordance with some embodiments. FIG. 3 is a structural diagram of a display surface of a display module in accordance with some embodiments.

As shown in FIG. 2, some embodiments of the present disclosure provide a display module 100. The display module 100 includes a flexible display panel 10, a polarizer 20 and a mirror structure layer 40.

The flexible display panel 10 may be an OLED display panel. The type of the flexible display panel 10 is not limited in embodiments of the present disclosure and may be provided according to actual needs.

The polarizer 20 is disposed on a display surface A1 of the flexible display panel 10. For example, the polarizer 20 may be a circular polarizer.

The mirror structure layer 40 is located on a side of the polarizer 20 away from the flexible display panel 10. When the display module 100 performs mirror display, the mirror structure layer 40 may be used to reflect external ambient light out of the display module 100, thereby achieving a mirror effect of the display module 100.

The polarizer 20 may be used to adjust a polarization direction of the display light of the display module 100 and adjust the ambient light incident on the display module 100 from outside, thereby adjusting the display effect and mirror effect of the display module 100.

For example, cooperation of a direction of an absorption axis of the polarizer 20 and a direction of a transmission axis of a mirror orientation layer 41 of the mirror structure layer 40 is used to allow the polarized light exiting after light emitted by light-emitting devices passing through the polarizer 20 to be almost completely transmitted through the mirror structure layer 40, and the display light of the display module 100 does not attenuate. Therefore, it may be beneficial for improving the display brightness of the display module 100 during display.

For example, the display module 100 has a display area AA. The display area AA includes a plurality of sub-pixels. Each sub-pixel includes a light-emitting device and a driving circuit. For example, the light-emitting device includes an anode, a light-emitting functional layer, and a cathode, and the driving circuit drives the light-emitting device to emit light.

When the display module 100 is in a mirror state, the polarizer 20 may be used to adjust light reflected by the anode in the light-emitting device, so as to avoid ghost image on the mirror surface of the display module 100.

However, it is found by the inventors of the present disclosure through research that strength of each film layer in the flexible display panel 10 is insufficient, and an elastic modulus of the polarizer 20 located between the flexible display panel 10 and the mirror structure layer 40 is relatively low. Since an elastic modulus of the flexible display panel 10 and the elastic modulus of the polarizer 20 are relatively low, when the display module 100 is assembled, a surface of the flexible display panel 10 and/or a surface of the polarizer 20 are prone to deformation or generate slight deformation. Since the mirror structure layer 40 is formed above the flexible display panel 10 and the polarizer 20, deformation of the surface of the flexible display panel 10 and deformation of the surface of the polarizer 20 are prone to cause slight wrinkles on the adjacent mirror structure layer 40.

As shown in FIG. 3, when the display module 100 performs mirror display, the mirror structure layer 40 needs to be used to reflect external ambient light out of the display module 100. However, since the mirror structure layer 40 has slight wrinkles, all reflected lights L2 formed by reflection of the light (ambient light) L1 incident on the wrinkle may have different reflection angles (there is an included angle θ between two reflected lights L2). As a result, orange peel patterns may occur when human eyes view the display module 100, thereby affecting the mirror effect of the display module 100. FIG. 3 only shows directions of lights after a single beam of light (ambient light) L1 is incident on the wrinkle of the mirror structure layer 40, but this does not mean that only a single beam of light (ambient light) L1 is incident on the mirror structure layer 40. For directions of lights after another light (ambient light) L1 is incident on the wrinkle of the mirror structure layer 40, reference may also be made to FIG. 3.

Some embodiments of the present disclosure provide a display module 100. With continued reference to FIG. 2, the display module 100 further includes a transparent support layer 30. The transparent support layer 30 is located on a side of the polarizer 20 away from the flexible display panel 10. The mirror structure layer 40 is located on a side of the transparent support layer 30 away from the polarizer 20. That is, the transparent support layer 30 is located between the mirror structure layer 40 and the polarizer 20.

An elastic modulus of the transparent support layer 30 is set to be greater than an elastic modulus of the polarizer 20. That is, a film layer with a high elastic modulus is provided below the mirror structure layer 40 (on a side of the mirror structure layer 40 away from the light exit surface of the display module 100).

In this way, the transparent support layer 30 has a relatively high elastic modulus, so that a surface of the transparent support layer 30 is not easy to deform, that is, it is not easy to cause deformation during assembly. As a result, the surface of the transparent support layer 30 may be maintained as a flat surface. For example, a height difference between any two points on a surface of the transparent support layer 30 proximate to the mirror structure layer 40 in a direction perpendicular to the light exit surface of the display module 100 is within a threshold range. The threshold range may be understood as a range within which the orange peel patterns will not be viewed when the human eyes view the mirror surface of the display module 100. For example, the height difference between any two points on the surface of the transparent support layer 30 proximate to the mirror structure layer 40 is 0. In this way, it may prevent the mirror structure layer 40 from generating wrinkles when the display module 100 is assembled, thereby improving the mirror effect of the display module 100.

In addition, the transparent support layer 30 has a relatively high elastic modulus. Based on this, even if the elastic modulus of the flexible display panel 10 and the elastic modulus of the polarizer 20 are relatively low, and slight deformation is prone to occur during assembly, since the transparent support layer 30 located above the flexible display panel 10 and the polarizer 20 (on a side of the flexible display panel 10 and the polarizer 20 proximate to the light exit surface of the display module 100) has a relatively high elastic modulus, the surface of the transparent support layer 30 proximate to the mirror structure layer 40 is not easy to deform (i.e., the surface of the transparent support layer 30 proximate to the mirror structure layer 40 may not be affected by the slight deformation), and may be maintained as a flat surface. Further, it may prevent the mirror structure layer 40 from generating wrinkles during assembly due to the influence of the film layers below, thereby helping to improve the mirror effect of the display module 100.

In summary, in the display module 100 provided by the embodiments of the present disclosure, a transparent support layer 30 with a high elastic modulus is provided between the mirror structure layer 40 and the polarizer 20. Since the transparent support layer 30 has a relatively high elastic modulus itself, the surface of the transparent support layer 30 is not prone to deformation and may play a role of supporting the mirror structure layer 40. It may prevent the mirror structure layer 40 from generating wrinkles during assembly of the display module 100 due to deformation of film layers with low elastic modulus such as the flexible display panel 10 and the polarizer 20, and keep the surface of the mirror structure layer 40 flat, so as to prevent the orange peel patterns from being produced when the human eyes view the display module 100, thereby improving the mirror effect of the display module 100.

FIG. 4 is a structural diagram of a display module in accordance with some other embodiments.

In some embodiments, as shown in FIG. 4, the display module 100 further includes a first adhesive layer Q1 and a second adhesive layer Q2. The first adhesive layer Q1 is located between the transparent support layer 30 and the polarizer 20. The second adhesive layer Q2 is located between the mirror structure layer 40 and the transparent support layer 30. The elastic modulus of the transparent support layer 30 is greater than an elastic modulus of the first adhesive layer Q1.

In the present embodiments, the transparent support layer 30 in the display module 100 may be bonded to the polarizer 20 by the first adhesive layer Q1, and may be bonded to the mirror structure layer 40 by the second adhesive layer Q2. The elastic modulus of the transparent support layer 30 is set to be greater than the elastic modulus of the first adhesive layer Q1. That is, the elastic modulus of the transparent support layer 30 is set to be greater than an elastic modulus of an adhesive layer below the mirror structure layer 40. The transparent support layer 30 may prevent the first adhesive layer Q1 from deforming after curing or prevent the first adhesive layer Q1 from deforming slightly caused by other reasons during assembly of the display module 100, where the slight deformation may cause wrinkles of the mirror structure layer 40. It is beneficial to further improve the mirror effect of the display module 100. The expression of below the mirror structure layer 40 refers to on a side of the mirror structure layer 40 proximate to the flexible display panel 10.

For example, the elastic modulus of the first adhesive layer Q1 and the elastic modulus of the second adhesive layer Q2 are generally less than 200 kPa.

In some examples, the material of the first adhesive layer Q1 may be an optical clear adhesive (OCA). The material of the first adhesive layer Q1 is not limited thereto in the present disclosure.

In some examples, a thickness of the first adhesive layer Q1 may be less than or equal to 50 μm. In a case where the thickness of the first adhesive layer Q1 is equal to or close to 50 μm, the thickness of the first adhesive layer Q1 is relatively large, and the first adhesive layer Q1 has relatively good adhesiveness and may bond the transparent support layer 30 well.

For example, the thickness of the first adhesive layer Q1 may also be in a range of 10 μm to 30 μm, inclusive.

In a case where the thickness of the first adhesive layer Q1 is equal to or close to 30 μm, the first adhesive layer Q1 may achieve relatively good adhesiveness and prevent the problem of being prone to deformation due to excessively large thickness. In a case where the thickness of the first adhesive layer Q1 is equal to or close to 10 μm, the first adhesive layer Q1 is relatively thin, which may well prevent the problem of being prone to deformation due to excessively large thickness, and may also meet the adhesiveness requirements of the first adhesive layer Q1.

For example, the thickness of the first adhesive layer Q1 may be any of 10 μm, 15 μm, 20 μm or 25 μm.

In some embodiments, as shown in FIG. 4, the elastic modulus of the transparent support layer 30 is greater than an elastic modulus of the second adhesive layer Q2.

With such setting, the elastic modulus of the transparent support layer 30 is greater than an elastic modulus of an adhesive layer above the mirror structure layer 40, that is, the elastic modulus of the transparent support layer 30 is greater than the elastic modulus of the adhesive layer adjacent to the mirror structure layer 40. It may prevent the second adhesive layer Q2 from deforming after curing or prevent the second adhesive layer Q2 from deforming slightly caused by other reasons during assembly of the display module 100, where the slight deformation may cause wrinkles of the mirror structure layer 40. It is beneficial to further improve the mirror effect of the display module 100. The expression of above the mirror structure layer 40 refers to on a side of the mirror structure layer 40 away from the flexible display panel 10.

It can be understood that in the display module 100 provided by some embodiments of the present disclosure, the elastic modulus of the transparent support layer 30 may be not only greater than the elastic modulus of the first adhesive layer Q1, but also greater than the elastic modulus of the second adhesive layer Q2.

In some examples, the material of the second adhesive layer Q2 may be the same as the material of the first adhesive layer Q1. The material of the second adhesive layer Q2 may be optical clear adhesive (OCA). It can be understood that in some other examples, the material of the second adhesive layer Q2 may be different from the material of the first adhesive layer Q1.

In some examples, a thickness of the second adhesive layer Q2 may be less than or equal to 50 μm. In a case where the thickness of the second adhesive layer Q2 is equal to or close to 50 μm, the thickness of the second adhesive layer Q2 is relatively large, and the second adhesive layer Q2 has relatively good adhesiveness and may bond the transparent support layer 30 well.

For example, the thickness of the second adhesive layer Q2 may also be in a range of 10 μm to 30 μm, inclusive.

In a case where the thickness of the second adhesive layer Q2 is equal to or close to 30 μm, the second adhesive layer Q2 may achieve relatively good adhesiveness and prevent the problem of being prone to deformation due to excessively large thickness. In a case where the thickness of the second adhesive layer Q2 is equal to or close to 10 μm, the second adhesive layer Q2 is relatively thin, which may well prevent the problem of being prone to deformation due to excessively large thickness, and may also meet the adhesiveness requirements of the second adhesive layer Q2.

For example, the thickness of the second adhesive layer Q2 may be any of 10 μm, 15 μm, 20 μm or 25 μm.

In some embodiments, the display module 100 further includes a fifth adhesive layer. The fifth adhesive layer may be located between the polarizer 20 and the flexible display panel 10. The polarizer 20 and the flexible display panel 10 are bonded by using the fifth adhesive layer.

In some examples, the material of the fifth adhesive layer may be the same as the material of the first adhesive layer Q1. The material of the fifth adhesive layer may be optical clear adhesive (OCA). It can be understood that in some other examples, the material of the fifth adhesive layer may be different from the material of the first adhesive layer Q1.

In some examples, a thickness of the fifth adhesive layer may be less than or equal to 50 μm. In a case where the thickness of the fifth adhesive layer is equal to or close to 50 μm, the thickness of the fifth adhesive layer is relatively large, and the fifth adhesive layer has relatively good adhesiveness and may bond the polarizer 20 well.

For example, the thickness of the fifth adhesive layer may also be in a range of 10 μm to 30 μm, inclusive.

In a case where the thickness of the fifth adhesive layer is equal to or close to 30 μm, the fifth adhesive layer may achieve relatively good adhesiveness and prevent the problem of being prone to deformation due to excessively large thickness. In a case where the thickness of the fifth adhesive layer is equal to or close to 10 μm, the fifth adhesive layer is relatively thin, which may well prevent the problem of being prone to deformation due to excessively large thickness, and may also meet the adhesiveness requirements of the fifth adhesive layer.

For example, the thickness of the fifth adhesive layer may be any of 10 μm, 15 μm, 20 μm or 25 μm.

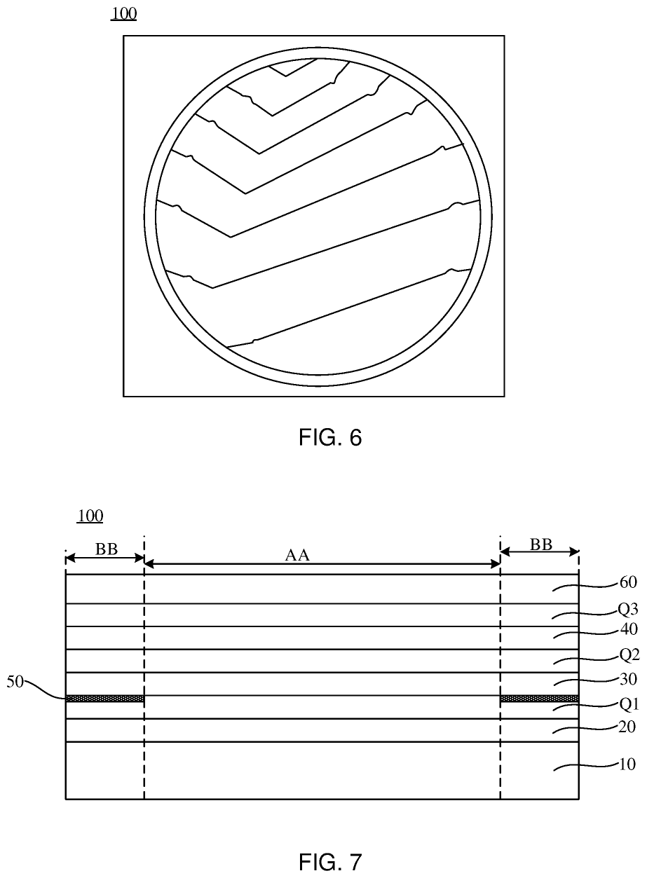

FIG. 5 is a structural diagram of a display module in accordance with some other embodiments. FIG. 6 is an electron microscope image of a display module in accordance with some embodiments.

In some embodiments, as shown in FIG. 5, the display module 100 has a display area AA and a peripheral area BB. The display module 100 further includes a light-shielding layer 50. The light-shielding layer 50 is located in the peripheral area BB. The light-shielding layer 50 is adjacent to the display area AA, and the light-shielding layer 50 is provided around the display area AA.

In the present embodiments, the display module 100 has the display area AA and the peripheral area BB. In some embodiments, the peripheral area BB may surround at least part of the display area AA. It can be understood that in some other embodiments, the peripheral area BB may be provided around the display area AA. The degree to which the peripheral area BB surrounds the display area AA is not limited in the present disclosure, and may be set according to actual product requirements.

The display area AA includes a plurality of sub-pixels. For example, the plurality of sub-pixels are described in the embodiments of the present disclosure by taking an example in which the plurality of sub-pixels are arranged in an array. Each sub-pixel includes a light-emitting device and a driving circuit. For example, the driving circuit includes a plurality of thin film transistors, and the light-emitting device includes an anode, a light-emitting functional layer, and a cathode. The driving circuit drives the light-emitting device to emit light.

The display module 100 further includes a light-shielding layer 50. The light-shielding layer 50 is located in the peripheral area BB. The light-shielding layer 50 is adjacent to the display area AA, and the light-shielding layer 50 is provided around the display area AA. The light-shielding layer 50 may block the light emitted by the light-emitting device in each sub-pixel from leaking through the peripheral area BB, thereby improving the display effect of the display module 100.

However, it may be found by the inventors of the present disclosure through research that in a case where the light-shielding layer 50 is disposed on a side of the mirror structure layer 40 away from the polarizer 20, an optical adhesive layer is generally used to bond the light-shielding layer 50 to the mirror structure layer 40. The light-shielding layer 50 is only located in the peripheral area BB, and the light-shielding layer 50 is adjacent to the display area AA. The light-shielding layer 50 has a certain thickness, and a thickness of the optical adhesive layer at a position corresponding to the light-shielding layer 50 is smaller than a thickness of the optical adhesive layer in the display area AA. As a result, the thickness of the optical adhesive layer located in the peripheral area BB is different from the thickness of the optical adhesive layer located in the display area AA. During assembly of the display module 100, the optical adhesive layer in the peripheral area BB and the optical adhesive layer in the display area AA may be subjected to uneven force, resulting in slight deformation of the optical adhesive layer at a position of the display area AA proximate to the peripheral area BB. The slight deformation may be prone to cause deformation of the adjacent mirror structure layer 40.

That is, in a case where the light-shielding layer 50 is disposed on a side of the mirror structure layer 40 away from the polarizer 20, it is prone to cause deformation of the mirror structure layer 40 at a position of the display area AA proximate to the peripheral area BB. As shown in FIG. 6, the existence of the deformation position may cause the light incident on the deformation position will be distorted when the display module 100 is in a mirror state, thereby affecting the mirror effect of the display module 100.

FIG. 6 shows a circular display module 100 as an example, but the shape of the display module 100 is not limited thereto in the embodiments of the present disclosure. In some other embodiments, as shown in FIG. 1, the display module 100 may be in a shape of a rectangle.

In some embodiments of the present disclosure, as shown in FIG. 5, the light-shielding layer 50 is located in the peripheral area BB and between the first adhesive layer Q1 and the transparent support layer 30. The light-shielding layer 50 is adjacent to the display area AA, and the light-shielding layer 50 is provided around the display area AA.

The light-shielding layer 50 is provided between the first adhesive layer Q1 and the transparent support layer 30. That is, the light-shielding layer 50 is provided on a side of the transparent support layer 30 away from the mirror structure layer 40. Since the transparent support layer 30 has a high elastic modulus, the transparent support layer 30 is not prone to deformation, thereby ensuring that the surface of the transparent support layer 30 proximate to the mirror structure layer 40 may remain as a flat surface. Based on this, the transparent support layer 30 may avoid deformation of the mirror structure layer 40 at the position of the display area AA proximate to the peripheral area BB caused by deformation of the first adhesive layer Q1 at the position of the display area AA proximate to the peripheral area BB due to the light-shielding layer 50. Therefore, it may prevent the light incident on the deformation position from being distorted when the display module 100 is in a mirror state, thereby improving the mirror effect of the display module 100.

In some embodiments, as shown in FIG. 5, the light-shielding layer 50 includes a light-shielding material. For example, the light-shielding layer 50 includes an ink layer. For example, the light-shielding layer 50 includes black ink. The ink layer may block the light emitted by the light-emitting device in each sub-pixel from leaking through the peripheral area BB, thereby improving the display effect of the display module 100.

In some embodiments, as shown in FIG. 5, the light-shielding layer 50 may be formed on a surface of the transparent support layer 30 proximate to the first adhesive layer Q1 by at least one of a glass direct molding (GDM) process, a screen transfer printing process and a pad printing process. The present disclosure does not limit the manner of forming the light-shielding layer 50.

In some embodiments, as shown in FIG. 2, 4 or 5, a thickness of the transparent support layer 30 in the display module 100 is greater than or equal to 20 μm.

In a case where the thickness of the transparent support layer 30 is equal to or close to 20 μm, the transparent support layer 30 is relatively thin, which allows the transparent support layer 30 to have relatively good flexibility and ductility, and also allows the transparent support layer 30 to have a certain hardness. The transparent support layer 30 may meet the requirements of the mirror structure layer 40 for the support force and is more convenient for bending, and may be suitable for the flexible display panel 10 and facilitate bending of the display module 100. In addition, setting the thickness of the transparent support layer 30 to be equal to or close to 20 μm may not result in an increase of the manufacturing difficulty cause by the inability of existing process methods due to the excessively thin transparent support layer 30.

In some examples, the thickness of the transparent support layer 30 is greater than or equal to 30 μm.

In a case where the thickness of the transparent support layer 30 is equal to or close to 30 μm, the process difficulty of manufacturing the transparent support layer 30 may be reduced. In addition, the supporting force of the transparent support layer 30 may increase to a certain extent, which may play a role of supporting the mirror structure layer 40 rather well, prevent the mirror structure layer 40 from generating wrinkles and other slight deformations, and improve the mirror effect of the display module 100. Moreover, the transparent support layer 30 may also be allowed to have a certain flexibility and ductility, so that the transparent support layer 30 may meet the requirements of the display module 100 for bending.

In some embodiments, as shown in FIG. 2, 4 or 5, a thickness of the transparent support layer 30 in the display module 100 is less than or equal to 100 μm.

In a case where the thickness of the transparent support layer 30 is equal to or close to 100 μm, the transparent support layer 30 is relatively thick and has a rather good supporting force. The transparent support layer 30 is not prone to deformation and may play a role of supporting the mirror structure layer 40 rather well, thereby preventing the mirror structure layer 40 from generating wrinkles and other slight deformations, and improving the mirror effect of the display module 100. Moreover, the transparent support layer 30 may not be too thick, that is, the transparent support layer 30 still has a certain flexibility and ductility, so that the transparent support layer 30 may meet the requirements of the display module 100 for bending.

In some examples, the thickness of the transparent support layer 30 is less than or equal to 70 μm.

In a case where the thickness of the transparent support layer 30 is equal to or close to 70 μm, the transparent support layer 30 may have a good support property and rather good flexibility and ductility, which may not only meet the requirements of supporting the mirror structure layer 40 but also meet the requirements of the display module 100 for bending rather well.

In some embodiments, a thickness of the transparent support layer 30 may be in a range of 30 μm to 70 μm, inclusive. Such a setting may cause the transparent support layer 30 to meet the requirements of the mirror structure layer 40 for the support force and to meet the requirements of the display module 100 for bending.

In summary, in a case where the thickness of the transparent support layer 30 in the display module 100 is in a range of 10 μm to 100 μm, the transparent support layer 30 has good flexibility and ductility, as well as good hardness. The transparent support layer 30 may not only meet the requirements of the display module 100 for bending, but also be not prone to deformation, so that the surface of the transparent support layer 30 may be maintained as a flat surface. Therefore, the transparent support layer 30 is used to prevent the mirror structure layer 40 from generating wrinkles and other slight deformations, thereby improving the mirror effect of the display module 100. The numerical value of the thickness of the transparent support layer 30 is not limited in the embodiments of the present disclosure. The larger the thickness of the transparent support layer 30, the higher the hardness of the transparent support layer 30, and the worse the flexibility of the transparent support layer 30. The smaller the thickness of the transparent support layer 30, the lower the hardness of the transparent support layer 30, and the better the flexibility of the transparent support layer 30. Based on this, the thickness of the transparent support layer 30 may be adjusted according to the actual needs of the display module 100.

For example, the thickness of the transparent support layer 30 may be any of 30 μm, 35 μm, 40 μm, 45 μm or 50 μm.

In some embodiments, as shown in FIG. 2, 4 or 5, the elastic modulus of the transparent support layer 30 in the display module 100 is in a range of 4 GPa to 200 GPa, inclusive.

In a case where the elastic modulus of the transparent support layer 30 is equal to or close to 4 GPa, the elastic modulus of the transparent support layer 30 is relatively low, but still satisfies the requirements that the elastic modulus of the transparent support layer 30 is greater than the elastic modulus of the polarizer 20, and the elastic modulus of the transparent support layer 30 is greater than the elastic modulus of the first adhesive layer Q1. Therefore, the transparent support layer 30 may be not prone to deformation, that is, the surface of the transparent support layer 30 proximate to the mirror structure layer 40 may be a flat surface. The transparent support layer 30 may play a role of supporting the mirror structure layer 40, keep the surface of the mirror structure layer 40 flat, and prevent the mirror structure layer 40 from generating wrinkles and other slight deformations, thereby improving the mirror effect of the display module 100. Moreover, in the case where the elastic modulus of the transparent support layer 30 is equal to or close to 4 GPa, the elastic modulus of the transparent support layer 30 is relatively low, which may prevent the hardness of the transparent support layer 30 from being excessively high and make the transparent support layer 30 have good ductility and flexibility, thereby meeting the requirements of the display module 100 for bending.

In a case where the elastic modulus of the transparent support layer 30 is equal to or close to 200 GPa, the elastic modulus of the transparent support layer 30 is relatively high, but may not make the hardness of the transparent support layer 30 excessively high. That is, in this case, the transparent support layer 30 still has a certain ductility and flexibility, and still meets the requirements of the display module 100 for bending. In addition, in the case where the elastic modulus of the transparent support layer 30 is equal to or close to 200 GPa, the elastic modulus of the transparent support layer 30 is relatively high, and the hardness of the transparent support layer 30 is rather high, so that the transparent support layer 30 is not prone to deformation. Therefore, it may be convenient to make the surface of the transparent support layer 30 proximate to the mirror structure layer 40 a flat surface during assembly of the display module 100. The transparent support layer 30 supports the mirror structure layer 40, and the flat surface of the transparent support layer 30 may effectively prevent the mirror structure layer 40 from generating wrinkles and other slight deformations, thereby improving the mirror effect of the display module 100.

In some embodiments, the elastic modulus of the transparent support layer 30 is in a range of 10 GPa to 180 GPa, inclusive. In some other embodiments, the elastic modulus of the transparent support layer 30 is in a range of 20 GPa to 160 GPa, inclusive.

In some other embodiments, as shown in FIG. 2, 4 or 5, the elastic modulus of the transparent support layer 30 in the display module 100 is in a range of 30 GPa to 150 Gpa, inclusive, for example, in a range of 30 GPa to 100 GPa, inclusive.

In a case where the elastic modulus of the transparent support layer 30 is equal to or close to 30 GPa, the transparent support layer 30 may have relatively good ductility and flexibility, as well as rather high hardness. Therefore, the transparent support layer 30 is prevented from being deformed rather well when the display module 100 is assembled or in other states, so that the surface of the transparent support layer 30 still remains as a flat surface. Furthermore, the transparent support layer 30 may be well utilized to prevent the mirror structure layer 40 from generating wrinkles and other slight deformations, thereby improving the mirror effect of the display module 100. Moreover, the transparent support layer 30 has good ductility and flexibility, and may also enable the transparent support layer 30 to meet the requirements of the display module 100 for bending.

In a case where the elastic modulus of the transparent support layer 30 is equal to or close to 150 GPa, the transparent support layer 30 may have relatively high hardness, as well as good ductility and flexibility. Therefore, the transparent support layer 30 may match the flexible display panel 10 well, so as to meet the requirements of the display module 100 for bending and avoid bending marks when the flexible display panel 10 or the display module 100 is bent, thereby improving the service life of the display module 100. In addition, the transparent support layer 30 has relatively high hardness, so that the transparent support layer 30 is not prone to deformation when the display module 100 is assembled or in other states, and the surface of the transparent support layer 30 still remains as a flat surface. Furthermore, the transparent support layer 30 may be used to prevent the mirror structure layer 40 from generating wrinkles and other slight deformations, thereby improving the mirror effect of the display module 100.

In some other embodiments, the elastic modulus of the transparent support layer 30 is in a range of 40 GPa to 130 GPa, inclusive. In some other embodiments, the elastic modulus of the transparent support layer 30 is in a range of 50 GPa to 110 GPa, inclusive.

In some other embodiments, as shown in FIG. 2, 4 or 5, the elastic modulus of the transparent support layer 30 in the display module 100 is in a range of 60 GPa to 100 GPa, inclusive, for example, in a range of 60 GPa to 80 GPa, inclusive.

In a case where the elastic modulus of the transparent support layer 30 is equal to or close to 60 GPa, the transparent support layer 30 may have relatively good ductility and flexibility, as well as rather high hardness. Therefore, the transparent support layer 30 is prevented from being deformed rather well when the display module 100 is assembled or in other states, so that the surface of the transparent support layer 30 still remains as a flat surface. Furthermore, the transparent support layer 30 may be well utilized to prevent the mirror structure layer 40 from generating wrinkles and other slight deformations, thereby improving the mirror effect of the display module 100. Moreover, the transparent support layer 30 has good ductility and flexibility, and may also enable the transparent support layer 30 to meet the requirements of the display module 100 for bending.

It can be understood that in this case, the hardness of the transparent support layer 30 will not be excessively high due to the excessively high elastic modulus of the transparent support layer 30. That is, in this case, although the transparent support layer 30 has a certain flexibility, it is not sufficient to meet the requirement of folding of the display module 100 repeatedly. Alternatively, the flexibility and ductility of the transparent support layer 30 will not be relatively good due to the excessively low elastic modulus of the transparent support layer 30. That is, in this case, although the transparent support layer 30 has a certain hardness, it is not sufficient to meet the requirement of the transparent support layer 30 not undergoing slight deformation every time it is subjected to external force or other circumstances. That is, in this case, the transparent support layer 30 has both good flexibility and good hardness, and the flexibility and the hardness of the transparent support layer 30 are in a relatively balanced state.

In a case where the elastic modulus of the transparent support layer 30 is equal to or close to 100 GPa, the transparent support layer 30 may have relatively high hardness, as well as good ductility and flexibility. Therefore, the transparent support layer 30 may match the flexible display panel 10 well, so as to meet the requirements of the display module 100 for bending and avoid bending marks when the flexible display panel 10 or the display module 100 is bent, thereby improving the service life of the display module 100. In addition, the transparent support layer 30 has relatively high hardness, so that the transparent support layer 30 is not prone to deformation when the display module 100 is assembled or in other states, and the surface of the transparent support layer 30 still remains as a flat surface. Furthermore, the transparent support layer 30 may be used to prevent the mirror structure layer 40 from generating wrinkles and other slight deformations, thereby improving the mirror effect of the display module 100.

It can be understood that in this case, the hardness of the transparent support layer 30 will not be excessively high due to the excessively high elastic modulus of the transparent support layer 30. That is, in this case, although the transparent support layer 30 has a certain flexibility, it is not sufficient to meet the requirement of folding of the display module 100 repeatedly. Alternatively, the flexibility and ductility of the transparent support layer 30 will not be relatively good due to the excessively low elastic modulus of the transparent support layer 30. That is, in this case, although the transparent support layer 30 has a certain hardness, it is not sufficient to meet the requirement of the transparent support layer 30 not undergoing slight deformation every time it is subjected to external force or other circumstances. That is, in this case, the transparent support layer 30 has both good flexibility and good hardness, and the flexibility and the hardness of the transparent support layer 30 are in a relatively balanced state.

In summary, in a case where the elastic modulus of the transparent support layer 30 in the display module 100 is in a range of 60 GPa to 100 GPa, the transparent support layer 30 has both good flexibility and good hardness. The transparent support layer 30 may not only meet the requirements of the display module 100 for bending, but also be not prone to deformation, so that the surface of the transparent support layer 30 may be maintained as a flat surface. Therefore, the transparent support layer 30 is used to prevent the mirror structure layer 40 from generating wrinkles and other slight deformations, thereby improving the mirror effect of the display module 100.

In some other embodiments, the elastic modulus of the transparent support layer 30 is in a range of 60 GPa to 90 GPa, inclusive. Alternatively, in some other embodiments, the elastic modulus of the transparent support layer 30 is in a range of 65 GPa to 80 GPa, inclusive.

It can be understood that in some of the above embodiments of the present disclosure, the transparent support layer 30 may be in a range of 4 GPa to 200 GPa. Within 4 GPa to 200 GPa, the transparent support layer 30 may not only meet the requirements of the display module 100 for bending, but also be not prone to deformation, so that the surface of the transparent support layer 30 remains as a flat surface. The transparent support layer 30 is used to prevent the mirror structure layer 40 from generating wrinkles and other slight deformations, thereby improving the mirror effect of the display module 100.

The specific value of the elastic modulus of the transparent support layer 30 is not limited thereto. The higher the elastic modulus of the transparent support layer 30, the higher the hardness of the transparent support layer 30, and the worse the flexibility of the transparent support layer 30. The lower the elastic modulus of the transparent support layer 30, the lower the hardness of the transparent support layer 30, and the better the flexibility of the transparent support layer 30. Therefore, the elastic modulus of the transparent support layer 30 may be adjusted according to the actual needs of the display module 100.

For example, the elastic modulus of the transparent support layer 30 is approximately any of 60 GPa, 72 GPa or 80 GPa.

In addition, considering an example where the elastic modulus of the transparent support layer 30 is approximately 72 GPa, due to certain uncontrollable errors (e.g., manufacturing process errors, equipment accuracy, and measurement errors), the error floating of the elastic modulus of the transparent support layer 30 within a range of 10%×72 GPa may also be considered that the elastic modulus of the transparent support layer 30 meets the limiting condition of being equal to 72 GPa.

In some examples, the error floating of the elastic modulus of the transparent support layer 30 is within a range of 8%×72 GPa, which may also be considered that the elastic modulus of the transparent support layer 30 meets the limiting condition of being equal to 72 GPa. In some examples, the error floating of the elastic modulus of the transparent support layer 30 within a range of 5%×72 GPa, which may also be considered that the elastic modulus of the transparent support layer 30 meets the limiting condition of being equal to 72 GPa.

In some embodiments, as shown in FIG. 2, 4 or 5, the transmittance of the transparent support layer 30 in the display module 100 is greater than or equal to 95%.

Since the transmittance of the transparent support layer 30 is greater than or equal to 95%, the transparent support layer 30 is a highly transparent material, which may be beneficial to increase the light transmittance. That is, the transparent support layer 30 may, on a basic of preventing the light transmittance of the display module 100 from being affected, make the surface of the transparent support layer 30 proximate to the mirror structure layer 40 not easily deformed and remain as a flat surface to support the mirror structure layer 40, so as to prevent the mirror structure layer 40 from generating wrinkles and other slight deformations, thereby improving the mirror effect of the display module 100.

In some embodiments, the transmittance of the transparent support layer 30 in the display module 100 is greater than or equal to 97%, which may further improve the light transmittance of the display module 100.

In some embodiments, as shown in FIG. 2, 4 or 5, the material of the transparent support layer 30 includes at least one of inorganic glass, thermoplastic rubber, colorless polyimide or organic glass. The inorganic glass includes ultra thin glass.

In some examples, the material of the transparent support layer 30 may be inorganic glass. The inorganic glass may be silicate non-metallic material. The inorganic glass may include non-bendable ordinary glass and bendable ultra thin glass (UTG).

The difference between two types of inorganic glass is described in detail below.

In the first type, the inorganic glass may include non-bendable ordinary glass. That is, the material of the transparent support layer 30 is ordinary glass.

The elastic modulus of the ordinary glass is generally greater than 72 GPa, and the thickness of the ordinary glass is approximately 700 μm. As a result, the ordinary glass has a relatively high hardness, so that the surface of the ordinary glass is less likely to be deformed, and the ordinary glass has relatively good support performance, which may meet the needs of the transparent support layer 30. That is, in a case where the material of the transparent support layer 30 is ordinary glass, the surface of the transparent support layer 30 proximate to the mirror structure layer 40 may be less likely to deform and may remain as a flat surface. Therefore, the mirror structure layer 40 may be effectively supported, and the mirror structure layer 40 may be prevented from generating wrinkles and other slight deformations, thereby improving the mirror effect of the display module 100.

Moreover, the ordinary glass also has high transmittance, which may also prevent the transparent support layer 30 from affecting the light transmittance of the display module 100, thereby improving the display quality of the display module 100.

In addition, the ordinary glass also has effects of high temperature resistance, light weight, environmental protection and low cost, and may be widely used.

Furthermore, it will be noted that due to certain uncontrollable errors (e.g., manufacturing process errors, equipment accuracy, and measurement errors), the error floating of the thickness of the ordinary glass within a range of 15%×700 μm may also be considered that the thickness of the ordinary glass meets the limiting condition of being equal to 700 μm.

In some examples, the error floating of the thickness of the ordinary glass is within a range of 10%×700 μm, which may also be considered that the thickness of the ordinary glass meets the limiting condition of being equal to 700 μm. In some examples, the error floating of the thickness of the ordinary glass is within a range of 8%×700 μm, which may also be considered that the thickness of the ordinary glass meets the limiting condition of being equal to 700 μm. Alternatively, in some examples, the error floating of the thickness of the ordinary glass is within a range of 5%×700 μm, which may also be considered that the thickness of the ordinary glass meets the limiting condition of being equal to 700 μm.

In the second type, the inorganic glass may include bendable ultra thin glass (UTG). That is, the material of the transparent support layer 30 is ultra thin glass (UTG).

Compared with the non-bendable ordinary glass, the ultra thin glass (UTG) has higher strength and better ductility and flexibility. That is, in a case where the material of the transparent support layer 30 is ultra thin glass (UTG), the transparent support layer 30 may meet the requirements of the display module 100 for bending and facilitate the realization of a foldable display module or a scrollable display module.

Moreover, the elastic modulus of the ultra thin glass (UTG) is greater than 4 GPa. The elastic modulus of the ultra thin glass (UTG) is also greater than the elastic modulus of the flexible display panel 10 and the elastic modulus of the polarizer 20. The surface of the ultra thin glass (UTG) is not prone to deformation and has good support performance, which may satisfy the requirements of the transparent support layer 30. That is, in a case where the material of the transparent support layer 30 is ultra thin glass (UTG), the surface of the transparent support layer 30 proximate to the mirror structure layer 40 may be less likely to deform and may remain as a flat surface. Therefore, the mirror structure layer 40 may be effectively supported, and the mirror structure layer 40 may be prevented from generating wrinkles and other slight deformations, thereby improving the mirror effect of the display module 100. In addition, the transmittance of the ultra thin glass (UTG) is greater than or equal to 98%, that is, the ultra thin glass (UTG) also has ultra-high transmittance, which may be beneficial to improve the light transmittance of the display module 100, thereby improving the display quality of the display module 100.

In addition, the thickness of the ultra thin glass (UTG) is smaller than that of the ordinary glass. In some examples, the material of the transparent support layer 30 is ultra thin glass (UTG), and the thickness of the ultra thin glass (UTG) may be less than or equal to 200 μm.

In a case where the thickness of the ultra thin glass (UTG) is equal to or close to 200 μm, the ultra thin glass (UTG) may have a relatively high hardness, that is, the transparent support layer 30 may have a relatively high hardness, so that the transparent support layer 30 is not prone to deformation. Therefore, the surface of the transparent support layer 30 proximate to the mirror structure layer 40 may be less likely to deform and may remain as a flat surface. Thus, the mirror structure layer 40 may be effectively supported, and the mirror structure layer 40 may be prevented from generating wrinkles and other slight deformations, thereby improving the mirror effect of the display module 100.

In some other examples, the material of the transparent support layer 30 is ultra thin glass (UTG). The thickness of the ultra-thin glass (UTG) may be less than or equal to 100 μm.

In a case where the thickness of the ultra thin glass (UTG) is equal to or close to 100 μm, compared with the ultra thin glass (UTG) with a thickness of 200 μm and compared with the ordinary glass, the transparent support layer 30 may be made relatively thin, which may be beneficial to the lightness and thinness of the display module 100, and to improve the ductility and flexibility of the transparent support layer 30 and facilitate the bending of the display module 100. Moreover, the thickness of the ultra thin glass (UTG) may be less than or equal to 100 μm, which may meet the requirements of the transparent support layer 30 for hardness. As a result, the surface of the transparent support layer 30 proximate to the mirror structure layer 40 may be less likely to deform and may remain as a flat surface. Therefore, the mirror structure layer 40 may be effectively supported, and the mirror structure layer 40 may be prevented from generating wrinkles and other slight deformations, thereby improving the mirror effect of the display module 100.

In some other examples, the material of the transparent support layer 30 is ultra thin glass (UTG). The thickness of the ultra thin glass (UTG) is in a range of 30 μm to 70 μm, inclusive.

In a case where the thickness of the ultra thin glass (UTG) is equal to or close to 30 μm, the transparent support layer 30 may have relatively good ductility and flexibility, which is beneficial to the bending of the display module 100. In addition, the thickness of the ultra thin glass (UTG) may be reduced by an order of magnitude compared to the thickness of the ordinary glass, which may be beneficial to making the display module 100 thin and light. Moreover, in the case where the thickness of the ultra thin glass (UTG) is equal to or close to 30 μm, the transparent support layer 30 may have a certain hardness, so that the surface of the transparent support layer 30 proximate to the mirror structure layer 40 may be less likely to deform and may remain as a flat surface. Therefore, the mirror structure layer 40 may be effectively supported, and the mirror structure layer 40 may be prevented from generating wrinkles and other slight deformations, thereby improving the mirror effect of the display module 100.

In a case where the thickness of the ultra thin glass (UTG) is equal to or close to 70 μm, the transparent support layer 30 may have relatively high hardness, so that the surface of the transparent support layer 30 proximate to the mirror structure layer 40 may be less likely to deform and may remain as a flat surface. Therefore, the mirror structure layer 40 may be effectively supported, and the mirror structure layer 40 may be prevented from generating wrinkles and other slight deformations, thereby improving the mirror effect of the display module 100. In addition, the thickness of the ultra thin glass (UTG) may be reduced by an order of magnitude compared to the thickness of the ordinary glass, which may be beneficial to making the display module 100 thin and light. Moreover, in the case where the thickness of the ultra thin glass (UTG) is equal to or close to 70 μm, the transparent support layer 30 may have a certain ductility and flexibility, which is beneficial to the bending of the display module 100.

In summary, in a case where the material of the transparent support layer 30 is inorganic glass, regardless of whether the inorganic glass is non-bendable ordinary glass or bendable ultra thin glass (UTG), the surface of the transparent support layer 30 proximate to the mirror structure layer 40 may be less likely to deform and may remain as a flat surface. Therefore, the mirror structure layer 40 may be effectively supported, and the mirror structure layer 40 may be prevented from generating wrinkles and other slight deformations, thereby improving the mirror effect of the display module 100. The specific material of the transparent support layer 30 may be adjusted according to the requirements of the display module 100 for bending. For example, if the display module 100 needs to be bent, the ultra thin glass (UTG) is selected. The thicker the ultra thin glass (UTG), the higher the hardness of the ultra thin glass (UTG), and the worse the flexibility of the ultra thin glass (UTG). That is, the thickness of the transparent support layer 30 may be adjusted according to the required hardness and flexibility of the transparent support layer.

For example, the thickness of the ultra thin glass (UTG) may be 30 μm, 40 μm, 50 μm, 60 μm or 70 μm.

In some examples, the material of the transparent support layer 30 may be at least one of thermoplastic rubber (e.g., polyethylene terephthalate, PET), colorless polyimide (CPI) or organic glass (e.g., polymethyl methacrylate, PMMA).

Whether thermoplastic rubber (e.g., polyethylene terephthalate, PET), colorless polyimide (CPI) or organic glass (e.g., polymethyl methacrylate, PMMA) all meet the requirements of the transparent support layer 30 for the elastic modulus and transmittance and meet the requirements of the display module 100 for bending. In the embodiments of the present disclosure, the material of the transparent support layer 30 is not limited thereto, and may be provided according to the actual situation.

FIG. 7 is a structural diagram of a display module in accordance with some other embodiments.

In some embodiments, as shown in FIG. 7, the display module 100 further includes a protective cover plate 60 and a third adhesive layer Q3. The protective cover plate 60 is located on a side of the mirror structure layer 40 away from the transparent support layer 30. The third adhesive layer Q3 is located between the protective cover plate 60 and the mirror structure layer 40.

In the present embodiments, the display module 100 further includes a protective cover plate 60. The protective cover plate 60 is located on the side of the mirror structure layer 40 away from the transparent support layer 30. The protective cover plate 60 is bonded to the mirror structure layer 40 by the third adhesive layer Q3. The protective cover plate 60 may be used to protect the flexible display panel 10 to prevent the flexible display panel 10 from being scratched, thereby extending the service life of the display module 100.

The material of the protective cover plate 60 includes at least one of inorganic glass, thermoplastic rubber, colorless polyimide or organic glass.

In some examples, the material of the protective cover plate 60 may be inorganic glass. The inorganic glass may include non-bendable ordinary glass and bendable ultra thin glass (UTG).

The difference between two types of inorganic glass is described in detail below.

In the first type, the inorganic glass may include non-bendable ordinary glass. That is, the material of the protective cover plate 60 is ordinary glass.

The elastic modulus of the ordinary glass is generally greater than 72 GPa, and the thickness of the ordinary glass is approximately 700 μm. As a result, the ordinary glass has a relatively high hardness, that is, the protective cover plate 60 has a relatively hardness. The flexible display panel 10 may be effectively protected, and the flexible display panel 10 may be prevented from being scratched.

Moreover, the ordinary glass also has high transmittance, so that the protective cover plate 60 has a high transmittance, so as to prevent the transparent support layer 30 from affecting the light transmittance of the display module 100, thereby improving the display quality of the display module 100.

In addition, the ordinary glass also has effects of high temperature resistance, light weight, environmental protection and low cost, and may be widely used.

In the second type: the inorganic glass may include bendable ultra thin glass (UTG). That is, the material of the protective cover plate 60 is ultra thin glass (UTG).

Compared with the non-bendable ordinary glass, the ultra thin glass (UTG) has higher strength and better ductility and flexibility. That is, in a case where the material of the protective cover plate 60 is ultra thin glass (UTG), the protective cover plate 60 may meet the requirements of the display module 100 for bending and facilitate the realization of a foldable display module or a scrollable display module. Moreover, the elastic modulus of ultra thin glass (UTG) is relatively high, and the protective cover plate 60 may also play a role of protecting the flexible display panel 10 and preventing the flexible display panel 10 from being scratched.

In addition, the transmittance of the ultra thin glass (UTG) is greater than or equal to 98%, that is, the protective cover plate 60 also has ultra-high transmittance, which may be beneficial to improve the light transmittance of the display module 100, thereby improving the display quality of the display module 100.

In some examples, the material of the protective cover plate 60 may be at least one of thermoplastic rubber (e.g., polyethylene terephthalate, PET), colorless polyimide (CPI) or organic glass (e.g., polymethyl methacrylate, PMMA).

In a case where the material of the protective cover plate 60 is ultra thin glass (UTG), thermoplastic rubber (e.g., polyethylene terephthalate, PET), colorless polyimide (CPI) or organic glass (e.g., polymethyl methacrylate, PMMA), the protective cover plate 60 may protect the flexible display panel 10 and prevent the flexible display panel 10 from being scratched, as well as meeting the requirements of the display modules 100 for flexibility. In the embodiments of the present disclosure, the material of the protective cover plate 60 is not limited thereto, and may be provided according to the actual situation.

In some examples, the material of the third adhesive layer Q3 may be optical clear adhesive (OCA). However, the material of the third adhesive layer Q3 in the present disclosure is not limited thereto.

In some examples, a thickness of the third adhesive layer Q3 may be less than 50 μm. In a case where the thickness of the third adhesive layer Q3 is equal to or close to 50 μm, the thickness of the third adhesive layer Q3 is relatively large, and the third adhesive layer Q3 has relatively good adhesiveness and may fix the protective cover plate 60 well.

For example, the thickness of the third adhesive layer Q3 may be in a range of 10 μm to 30 μm, inclusive. The thickness of the third adhesive layer Q3 may be any of 10 μm, 15 μm, 20 μm or 25 μm.

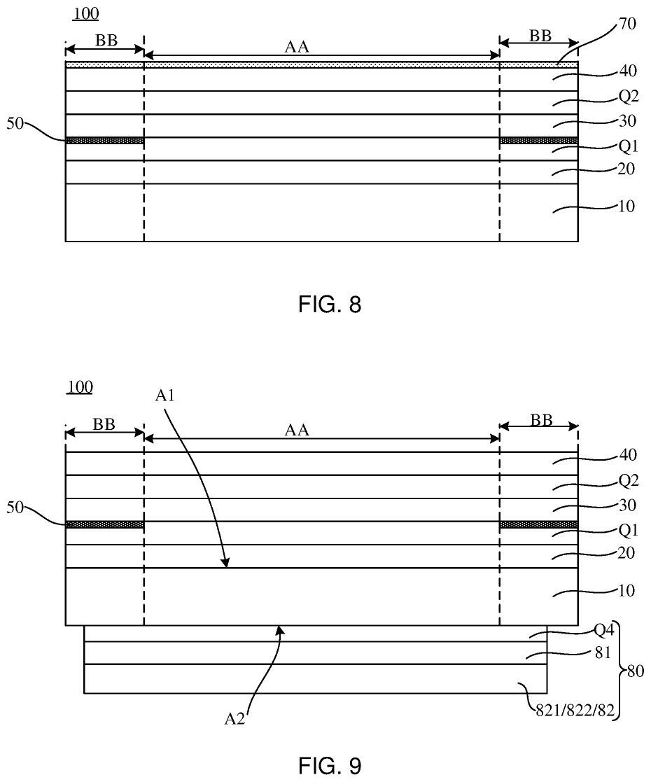

FIG. 8 is a structural diagram of a display module in accordance with some other embodiments.

In some embodiments, as shown in FIG. 8, the display module 100 further includes a hardened coating 70. The hardened coating 70 is formed on a surface of the mirror structure layer 40 away from the transparent support layer 30 by coating. For example, the hardened coating 70 may be a transparent hardened coating.

In the present embodiments, as shown in FIG. 8, the display module 100 may coat the surface of the mirror structure layer 40 away from the transparent support layer 30 with the hardened coating 70. The hardened coating 70 may increase rigidity of the surface of the mirror structure layer 40 away from the transparent support layer 30, and the hardened coating 70 may serve as a scratch-resistant coating. Therefore, the hardened coating 70 may be used to protect the flexible display panel 10, prevent the flexible display panel 10 from being scratched, and increase the service life of the display module 100. That is, the hardened coating 70 may function as the protective cover plate 60 in the display module 100 shown in FIG. 7.

Based on this, the hardened coating 70 in the display module 100 in the present embodiments may replace the protective cover plate 60 in the display module 100 shown in FIG. 7. Since the display module 100 shown in the present embodiments is not provided with a protective cover plate 60, it may be convenient for bending. Moreover, since the surface of the mirror structure layer 40 away from the transparent support layer 30 is directly coated with the hardened coating 70, the third adhesive layer Q3 in the display module 100 shown in FIG. 7 may also be omitted, which is more conducive to making the display module 100 thin and light.

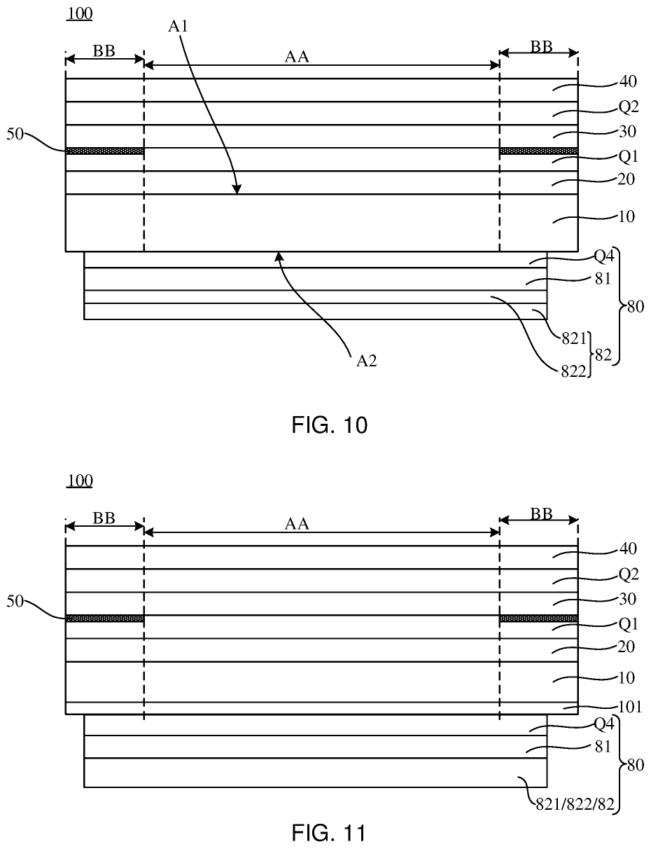

FIG. 9 is a structural diagram of a display module in accordance with some other embodiments. FIG. 10 is a structural diagram of a display module in accordance with some other embodiments.

In some embodiments, as shown in FIGS. 9 and 10, the display module 100 further includes a heat dissipation film 80. The heat dissipation film 80 is located on a back surface A2 of the flexible display panel 10, and the back surface A2 is a surface opposite to the display surface A1.

The heat dissipation film 80 may be bonded to the back surface A2 of the flexible display panel 10 by a fourth adhesive layer Q4. The heat generated during working of the flexible display panel 10 may be conducted to the heat dissipation film 80. The heat dissipation film 80 evenly distributes the heat throughout the heat dissipation film, thereby increasing the heat dissipation area, improving the heat dissipation efficiency, and avoiding display abnormality and other adverse problems caused by local overheating. As a result, the quality and the service life of the display module 100 may be improved.

In some examples, the heat dissipation film 20 includes a fourth adhesive layer Q4, a buffer layer 81 and a heat dissipation layer 82. The fourth adhesive layer Q4 is closer to the flexible display panel 10 than the buffer layer 81 and the heat dissipation layer 82. The buffer layer 81 is located on a side of the fourth adhesive layer Q4 away from the flexible display panel 10. The heat dissipation layer 82 is located on a side of the buffer layer 81 away from the fourth adhesive layer Q4. That is, the buffer layer 81 is located between the fourth adhesive layer Q4 and the heat dissipation layer 82.

The buffer layer 81 has certain elasticity and recovery properties. In a case where the display module 100 is impacted by an external force, the buffer layer 81 may buffer this part of the stress, so as to prevent damage to the flexible display panel 10 and improve the anti-fall performance of the display module 100.

In some examples, a material of the buffer layer 81 may be foam. For example, the material of the buffer layer 81 may be polyurethane (PU) foam, conductive foam, aluminum foil foam, rubber (CR) foam, and the like. Thus, it may be ensured that the buffer layer 81 has good thermal conductivity and may quickly conduct out the heat generated during working of the flexible display panel 10.

It can be understood that in some other examples, the material of the buffer layer 81 may be any or a combination of polyimide (PI), thermoplastic polyurethane (TPU), thermoplastic elastomer (TPE), or thermoplastic polyester elastomer (TPEE), which is not limited in the present disclosure; alternatively, or the material of the buffer layer 81 may be another material with certain elasticity and recovery properties.

In some examples, the material of the fourth adhesive layer Q4 may be optical clear adhesive (OCA), but the material of the fourth adhesive layer Q4 is not limited in the present disclosure.

In some examples, the fourth adhesive layer Q4 may include a textured adhesive layer, and vertical and horizontal mesh patterns may be imprinted on the adhesive surface by applying pressure through the grid. Thus, it may prevent curling caused by shrinkage of the adhesive layer and enhance tightness of attaching between the heat dissipation film 80 and the flexible display panel 10.

In some examples, the heat dissipation layer 82 includes a stainless steel layer 821 and/or a carbon fiber layer 822. The heat dissipation layer 82 includes the following types of structures.

In the first type, the heat dissipation layer 82 includes a stainless steel layer (SUS) 821. As shown in FIG. 9, in a case where the heat dissipation layer 82 is a stainless steel layer 821, the heat dissipation layer 82 may not only be used to conduct out the heat generated during working of the flexible display panel 10, but also play a good role of supporting the flexible display panel 10.

In the second type, the heat dissipation layer 82 includes a carbon fiber layer 822. As shown in FIG. 9, in a case where the heat dissipation layer 82 is a carbon fiber layer 822, since carbon fiber has high strength and good thermal conductivity, the heat dissipation layer 82 may not only be used to conduct out the heat generated during working of the flexible display panel 10, but also play a good role of supporting the flexible display panel 10.

In the third type, as shown in FIG. 10, the heat dissipation layer 82 includes a stainless steel layer 821 and a carbon fiber layer 822. The carbon fiber has high strength and good thermal conductivity, and a weight of the carbon fiber is lighter than that of the stainless steel. Therefore, on a basis of reducing the weight, the heat dissipation layer 82 may not only conduct out the heat generated during working of the flexible display panel 10, but also play a good role of supporting the flexible display panel 10.

FIG. 10 shows an example where the stainless steel layer 821 is located on a side of the carbon fiber layer 822 away from the buffer layer 81, but it is not limited thereto. The carbon fiber layer 822 may alternatively be located on a side of the stainless steel layer 821 away from the buffer layer 81. The specific structure of the heat dissipation layer 82 is not limited in the present disclosure, and may be provided according to actual situations.

FIG. 11 is a structural diagram of a display module in accordance with some other embodiments.

In some embodiments, the display module 100 further includes a back film 101. The back film 101 is located between the flexible display panel 10 and the heat dissipation film 80. The fourth adhesive layer Q4 in the heat dissipation film 80 is located between the heat dissipation layer 82 and the back film 101.

Since each film layer of the flexible display panel 10 has a relatively low elastic modulus, the flexible display panel 10 is too soft. The back film 101 may play a role of supporting the flexible display panel 10, and may improve the bending recovery performance, bending strength and deformation ability of the flexible display panel 10, and prevent cracking when the bending radius is small.

The material of the back film 101 is not limited in the embodiments of the present disclosure, and may use some materials with relatively high elastic modulus and capable of bending, such as resin material.

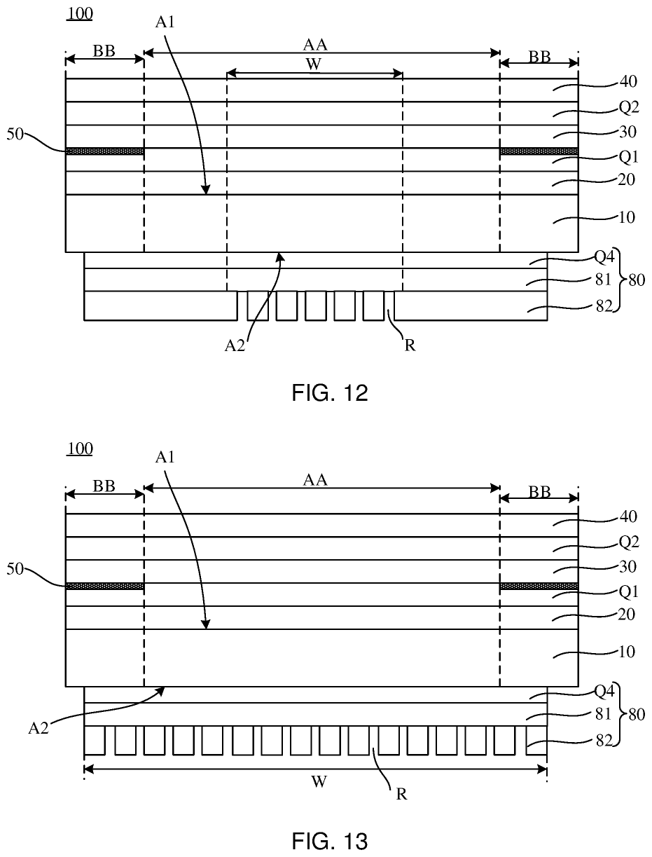

FIG. 12 is a structural diagram of a display module in accordance with some other embodiments.

In some embodiments, as shown in FIG. 12, the display module 100 includes a bendable area W. At least a portion of the heat dissipation layer 82 located in the bendable area W is configured to have a hollow structure R.

Since the heat dissipation layer 82 in the heat dissipation film 80 has relatively high hardness, at least a portion of the heat dissipation layer 82 located in the bendable area W is configured to have a hollow structure R, and thus the hollow structure R may be used to improve the bendability of the heat dissipation layer 82, so as to meet the requirements of the display module 100 for bendability.

FIG. 13 is a structural diagram of a display module in accordance with some other embodiments.

In some embodiments, as shown in FIGS. 12 and 13, the display module 100 includes a scrollable display module or a foldable display module.

As shown in FIG. 12, the display module 100 is a foldable display module, and the bendable area W is located in part of the display module 100. The bendable area W of the display module 100 may achieve bending based on the hollow structure R, thereby realizing the foldable display module.

In addition, the above heat dissipation layer 82 is described only in an example of a single folding structure, that is, the heat dissipation layer 82 is only folded in half once, and an exposed area of the corresponding display module 100 is reduced to half subsequently. However, it is not limited thereto. The heat dissipation layer 82 may alternatively be provided with a multiple folding structure, so that the display module 100 may be folded into a structure with a smaller exposed area subsequently. The multiple folding structure includes two or more folding portions, and the specific positions of the folding portions are not specifically limited.

As shown in FIG. 13, the display module 100 is a scrollable display module, and the bendable area W is located across the display module 100, so that the hollow structure R in the bendable area W may be used to achieve scrolling of the display module 100, thereby realizing the scrollable display module 100.

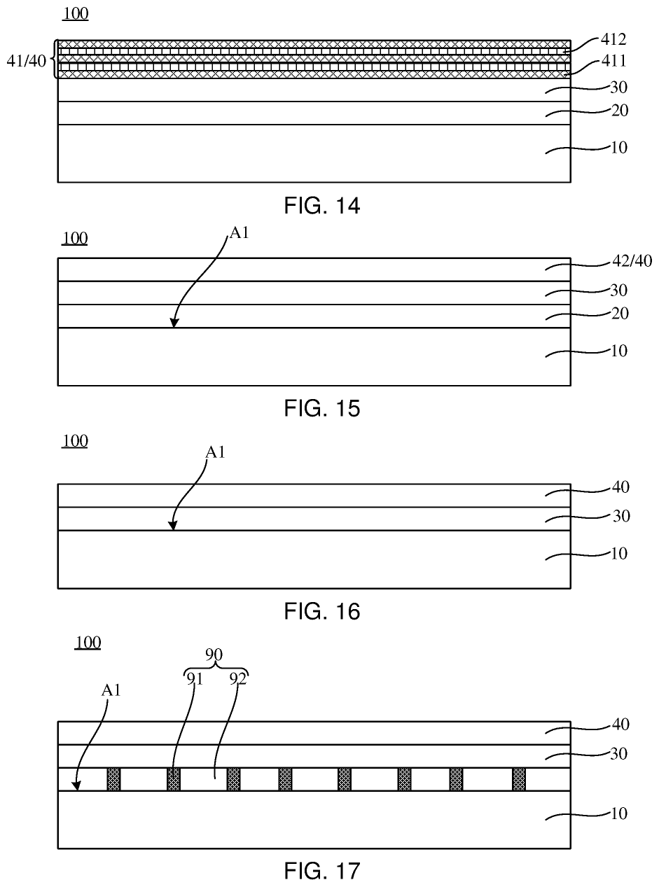

FIG. 14 is a structural diagram of a display module in accordance with some other embodiments.

In some embodiments, as shown in FIG. 14, the mirror structure layer 40 includes at least one mirror orientation layer 41. The direction of the transmission axis of the at least one mirror orientation layer 41 is perpendicular to the direction of the absorption axis of the polarizer 20.

With such provision, in a case where the display module 100 displays normally, since the direction of the transmission axis of the mirror orientation layer 41 is perpendicular to the direction of the absorption axis of the polarizer 20, the polarized light exiting after the light emitted by the light-emitting device passes through the polarizer 20 is almost completely transmitted through the mirror structure layer 40, and the display light of the display module 100 does not attenuate. Therefore, the display module 100 provided by the embodiments of the present disclosure may be beneficial to improving the display brightness during display. In a case where the display module 100 is in a mirror state, the principle of interference enhancement of the reflected light reflected after the ambient light enters each mirror orientation layer 41 may be used to achieve a high reflectivity, which is beneficial to improving the mirror effect of the display module 100.

FIG. 14 shows an example where the mirror structure layer 40 includes five mirror orientation layers 41. However, the number of the film layers of the mirror orientation layer(s) 41 in the mirror structure layer 40 is not limited in the embodiments of the present disclosure, which may be provided according to actual situations.

In some embodiments, as shown in FIG. 14, the mirror structure layer 40 includes five mirror orientation layers 41. The five mirror orientation layers 41 are three first mirror orientation layers 411 and two second mirror orientation layers 412. The second mirror orientation layer 412 is located between two first mirror orientation layers 411, and the first and the last of a plurality of mirror orientation layers 41 in the mirror structure layer 40 are both the first mirror orientation layers 411.

A refractive index of the first mirror orientation layer 411 is greater than a refractive index of the second mirror orientation layer 412.

The first mirror orientation layers 411 and the second mirror orientation layers 412 are arranged alternately, that is, the mirror orientation layers 41 with high refractive index and the mirror orientation layers 41 with low refractive index are alternately arranged. In a case where the display module 100 is in a mirror state, the principle of interference enhancement of the reflected light reflected after the ambient light enters each mirror orientation layer 41 may be used to achieve a high reflectivity, which is beneficial to improving the mirror effect of the display module 100.

In some examples, the material of the first mirror orientation layer 411 and the material of the second mirror orientation layer 412 may be the same. It can be understood that in some other examples, the material of the first mirror orientation layer 411 and the material of the second mirror orientation layer 412 may be different. The embodiments of the present disclosure do not limit this.

In some examples, all the first mirror orientation layers 411 have equal refractive indexes. Therefore, all the first mirror orientation layers 411 may be made of the same material.

In some examples, all the second mirror orientation layers 412 have equal refractive indexes. Therefore, all the second mirror orientation layers 412 may be made of the same material.

FIG. 15 is a structural diagram of a display module in accordance with some other embodiments.

In some embodiments, as shown in FIG. 15, the mirror structure layer 40 includes a metal reflective layer 42. The metal reflective layer 42 may have a high reflectivity to ambient light and act as a mirror to achieve the mirror state of the display module 100.

In some examples, the mirror structure layer 40 may be a single-layer metal reflective layer. For example, the material of the metal reflective layer may include at least one of aluminum, molybdenum, titanium, silver, and copper.

In some other examples, the mirror structure layer 40 may be of a multi-layer structure including the metal reflective layer. For example, the metal reflective layer may include a titanium metal layer, an aluminum metal layer and a titanium metal layer that are sequentially stacked. Alternatively, the metal reflective layer may include an indium tin oxide layer, a silver metal layer, and an indium tin oxide layer that are sequentially stacked.

In summary, some embodiments of the present disclosure provide a display module 100 and a display apparatus 200. The transparent support layer 30 is added in the display module 100, the transparent support layer 30 is disposed between the polarizer 20 and the mirror structure layer 40, and the elastic modulus of the transparent support layer 30 is greater than the elastic modulus of the polarizer 20. Since the elastic modulus of the transparent support layer 30 is relatively high, the surface of the transparent support layer 30 proximate to the mirror structure layer 40 is not likely to deform and remains as a flat surface, so as to prevent to be affected by deformation of film layers with relatively low elasticity such as the flexible display panel 10 and the polarizer 20. Therefore, it may prevent the mirror structure layer 40 from generating wrinkles during assembly due to the influence of the film layers below, and prevent the orange peel patterns from being produced when the human eyes view the display module 100, thereby helping to improve the mirror effect of the display module 100.

Some of the above embodiments of the present disclosure are exemplarily described by taking an example of the display module 100 including the polarizer 20. It is worth pointing out that in the display module 100 in the embodiments of the present disclosure, the polarizer 20 may not be provided, or the polarizer 20 may be replaced with a color film on encapsulation (COE, i.e., color film portions are directly formed on the encapsulation layer) structural layer, which will be introduced through some embodiments below.

FIG. 16 is a structural diagram of a display module in accordance with some other embodiments. FIG. 16 shows an example without the polarizer 20 provided.

In some embodiments, as shown in FIG. 16, the display module 100 includes a mirror structure layer 40 and a flexible display panel 10. The mirror structure layer 40 is located on a display surface A1 of the flexible display panel 10. When the display module 100 performs mirror display, the mirror structure layer 40 may be used to reflect external ambient light out of the display module 100, thereby achieving a mirror effect of the display module 100.

The difference from the display module 100 shown in FIG. 2 only lies in that the polarizer 20 is not provided, and other structures in the display module 100 are substantially the same. Based on this, due to the low elastic modulus of the flexible display panel 10, the mirror structure layer 40 in the display module 100 shown in the present embodiments will also generate slight deformation such as wrinkles during assembly of the display module 100. As a result, orange peel patterns may occur when human eyes view the display module 100, thereby affecting the mirror effect of the display module 100.

Some embodiments of the present disclosure provide a display module 100. As shown in FIG. 16, the display module 100 further includes a transparent support layer 30. The transparent support layer 30 is located between the mirror structure layer 40 and the flexible display panel 10, and the elastic modulus of the transparent support layer 30 is greater than the elastic modulus of the flexible display panel 10.

Therefore, in the display module 100 provided by the embodiments of the present disclosure, the transparent support layer 30 with a high elastic modulus is provided between the mirror structure layer 40 and the flexible display panel 10. Since the transparent support layer 30 has a relatively high elastic modulus itself, the surface of the transparent support layer 30 is not prone to deformation and may play a role of supporting the mirror structure layer 40. It may prevent the mirror structure layer 40 from generating wrinkles during assembly of the display module 100 due to deformation of film layers with low elastic modulus such as the flexible display panel 10, and keep the surface of the mirror structure layer 40 flat, so as to prevent the orange peel patterns from being produced when the human eyes view the display module 100, thereby improving the mirror effect of the display module 100.

The elastic modulus of the transparent support layer 30 is greater than the elastic modulus of the flexible display panel 10. There are two ways of understanding.

In the first way, the flexible display panel 10 includes an encapsulation layer proximate to the mirror structure layer 40. The encapsulation layer is used to prevent moisture and other impurities from entering the interior of the flexible display panel 10 and extend the service life of the flexible display panel 10. Based on this, the elastic modulus of the transparent support layer 30 may be greater than the elastic modulus of the encapsulation layer in the flexible display panel 10.

In the second way, the elastic modulus of the transparent support layer 30 is greater than an elastic modulus of a whole formed by the combination of various film layers in the flexible display panel 10.

The embodiments of the present disclosure do not limit the above two ways of understanding. Regardless of the above ways, the transparent support layer 30 may not be prone to deformation when the display module 100 is assembled, and the surface of the mirror structure layer 40 may be kept flat, so as to prevent the orange peel patterns from being produced when the human eyes view the display module 100, thereby improving the mirror effect of the display module 100.

In some of the above embodiments of the present disclosure, in addition to extending based on the polarizer 20, description of other features is also applicable to the display module without the polarizer 20 in the present embodiments, and details are not repeated here.

FIG. 17 is a structural diagram of a display module in accordance with some other embodiments. FIG. 17 shows an example of the display module with a COE structure.

In some embodiments, as shown in FIG. 17, based on the COE structure (i.e., color film portions are directly formed on the encapsulation layer), the display module 100 includes a mirror structure layer 40, a color film layer 90 and a flexible display panel 10. The color film layer 90 is located on a display surface A1 of the flexible display panel 10. The mirror structure layer 40 is located on a side of the color film layer 90 away from the flexible display panel 10.

When the display module 100 performs mirror display, the mirror structure layer 40 may be used to reflect external ambient light out of the display module 100, thereby achieving a mirror effect of the display module 100.

The difference from the display module 100 shown in FIG. 2 only lies in that the polarizer 20 is replaced with a color film on encapsulation (COE, i.e., color film portions are directly formed on the encapsulation layer) structural layer, and other structures in the display module 100 are substantially the same. Based on this, due to the low elastic modulus of the flexible display panel 10, the mirror structure layer 40 in the display module 100 shown in the present embodiments will also generate slight deformation such as wrinkles during assembly of the display module 100. As a result, orange peel patterns may occur when human eyes view the display module 100, thereby affecting the mirror effect of the display module 100.

Some embodiments of the present disclosure provide a display module 100. As shown in FIG. 17, the display module 100 further includes a transparent support layer 30. The transparent support layer 30 is located between the mirror structure layer 40 and the color film layer 90, and the elastic modulus of the transparent support layer 30 is greater than the elastic modulus of the flexible display panel 10.

Therefore, in the display module 100 provided by the embodiments of the present disclosure, the transparent support layer 30 with a high elastic modulus is provided between the mirror structure layer 40 and the color film layer 90. Since the transparent support layer 30 has a relatively high elastic modulus itself, the surface of the transparent support layer 30 is not prone to deformation and may play a role of supporting the mirror structure layer 40. It may prevent the mirror structure layer 40 from generating wrinkles during assembly of the display module 100 due to deformation of film layers with low elastic modulus such as the flexible display panel 10, and keep the surface of the mirror structure layer 40 flat, so as to prevent the orange peel patterns from being produced when the human eyes view the display module 100, thereby improving the mirror effect of the display module 100.

For the elastic modulus of the transparent support layer 30 is greater than the elastic modulus of the flexible display panel 10, reference may be made to the description corresponding to FIG. 16, and details are not repeated here.

In some other embodiments, as shown in FIG. 17, the elastic modulus of the transparent support layer 30 is greater than the elastic modulus of the color film layer 90.

The transparent support layer 30 with a high elastic modulus is provided between the mirror structure layer 40 and the color film layer 90. Since the transparent support layer 30 has a relatively high elastic modulus itself, the surface of the transparent support layer 30 is not prone to deformation and may play a role of supporting the mirror structure layer 40. It may prevent the mirror structure layer 40 from generating wrinkles during assembly of the display module 100 due to deformation of film layers with low elastic modulus such as the color film layer 90, and keep the surface of the mirror structure layer 40 flat, so as to prevent the orange peel patterns from being produced when the human eyes view the display module 100, thereby improving the mirror effect of the display module 100.

In some of the above embodiments of the present disclosure, in addition to extending based on the polarizer 20, other description are also applicable to the display module with the COE structure, and details are not repeated here.

In some other embodiments, as shown in FIG. 17, the elastic modulus of the transparent support layer 30 is greater than the elastic modulus of the flexible display panel 10, and the elastic modulus of the transparent support layer 30 is greater than the elastic modulus of the color film layer 90.

The transparent support layer 30 with a high elastic modulus is provided between the mirror structure layer 40 and the color film layer 90. Since the transparent support layer 30 has a relatively high elastic modulus itself, the surface of the transparent support layer 30 is not prone to deformation and may play a role of supporting the mirror structure layer 40. It may prevent the mirror structure layer 40 from generating wrinkles during assembly of the display module 100 due to deformation of film layers with low elastic modulus such as the flexible display panel 10 and the color film layer 90, and keep the surface of the mirror structure layer 40 flat, so as to prevent the orange peel patterns from being produced when the human eyes view the display module 100, thereby improving the mirror effect of the display module 100.

In some embodiments, as shown in FIG. 17, the color film layer 90 includes a separation pattern 91 and a plurality of color film portions 92, and the separation pattern 91 is used to separate the plurality of color film portions 92. The plurality of color film portions 92 include red color film portions, green color film portions, and blue color film portions.

Compared with the display module 100 shown in FIG. 2, the display module 100 shown in FIG. 17 does not need to use the polarizer 20, which is beneficial to reducing the cost of the display module 100. Moreover, with the polarizer-free technology, the power consumption of the screen may be rather low under the same display brightness. In addition, compared with the polarizer, the thickness of the screen may be significantly reduced, which is beneficial to extending the life of the flexible display panel 10 and improving the service life of the display module 100.

In some examples, the display module 100 has a display area and a peripheral area. The display area includes a plurality of sub-pixels. For example, the plurality of sub-pixels are described in the embodiments of the present disclosure by taking an example in which the plurality of sub-pixels are arranged in an array. Each sub-pixel includes a light-emitting device and a driving circuit. For example, the driving circuit includes a plurality of thin film transistors, and the light-emitting device includes an anode, a light-emitting functional layer, and a cathode. The driving circuit drives the light-emitting device to emit light.

The light-emitting devices may include red light-emitting devices, green light-emitting devices and blue light-emitting devices. The light-emitting functional layer in the blue light-emitting device has the lowest luminous efficiency, followed by the light-emitting functional layer in the red light-emitting device, and the light-emitting functional layer in the green light-emitting device has the highest luminous efficiency. Therefore, it may be set that the blue light-emitting device has the largest size, followed by the red light-emitting device, and the green light-emitting device has the smallest size, which is beneficial to improving the color shift of the display module 100.

It will be noted that FIG. 17 shows an example where all the color film portions 92 have the same sizes. In some other embodiments, the color film portions 92 of different colors may be set to have different sizes.

For example, the size of the blue color film portion is set corresponding to the size of the blue light-emitting device, the size of the green color film portion is set corresponding to the size of the green light-emitting device, and the size of the red color film portion is set corresponding to the size of the red light-emitting device. Such a setting may be beneficial to improving the color shift of the display module 100.

In summary, some embodiments of the present disclosure provide a display module 100 and a display apparatus 200. The transparent support layer 30 is added in the display module 100, the transparent support layer 30 is disposed between the color film layer 90 and the mirror structure layer 40, and the elastic modulus of the transparent support layer 30 is greater than the elastic modulus of the color film layer 90. Since the elastic modulus of the transparent support layer 30 is relatively high, the surface of the transparent support layer 30 proximate to the mirror structure layer 40 is not likely to deform and remains as a flat surface, so as to prevent to be affected by deformation of film layers with relatively low elasticity such as the flexible display panel 10. Therefore, it may prevent the mirror structure layer 40 from generating wrinkles during assembly due to the influence of the film layers below, and prevent the orange peel patterns from being produced when the human eyes view the display module 100, thereby helping to improve the mirror effect of the display module 100.

In the description of the specification, specific features, structures, materials or characteristics may be combined in any suitable manner in any one or more embodiments or examples.

The foregoing descriptions are merely specific implementation manners of the present disclosure, but the protection scope of the present disclosure is not limited thereto. Changes or replacements that any person skilled in the art could conceive of within the technical scope of the present disclosure shall all be included in the protection scope of the present disclosure. Therefore, the protection scope of the present disclosure shall be subject to the protection scope of the claims.

1. A display module, comprising:
a flexible display panel;
a polarizer located on a display surface of the flexible display panel;
a transparent support layer located on a side of the polarizer away from the flexible display panel; and
a mirror structure layer located on a side of the transparent support layer away from the polarizer, wherein
an elastic modulus of the transparent support layer is greater than an elastic modulus of the polarizer.

2. The display module according to claim 1, further comprising:
a first adhesive layer located between the transparent support layer and the polarizer; and
a second adhesive layer located between the mirror structure layer and the transparent support layer, wherein
the elastic modulus of the transparent support layer is greater than an elastic modulus of the first adhesive layer.

3. The display module according to claim 2, wherein the display module has a display area and a peripheral area; and the display module further comprises:
a light-shielding layer located in the peripheral area and located between the first adhesive layer and the transparent support layer; the light-shielding layer is adjacent to the display area, and the light-shielding layer surrounds the display area.

4. The display module according to claim 3, wherein
the light-shielding layer includes an ink layer.

5. The display module according to claim 1, wherein
a thickness of the transparent support layer is greater than or equal to 20 μm.

6. The display module according to claim 1, wherein
a thickness of the transparent support layer is less than or equal to 100 μm.

7. The display module according to claim 1, wherein
a thickness of the transparent support layer is in a range of 30 μm to 70 μm, inclusive.

8. The display module according to claim 1, wherein
the elastic modulus of the transparent support layer is in a range of 4 GPa to 200 GPa, inclusive.

9. The display module according to claim 1, wherein
the elastic modulus of the transparent support layer is in a range of 30 GPa to 100 GPa, inclusive.

10. The display module according to claim 1, wherein
the elastic modulus of the transparent support layer is in a range of 60 GPa to 80 GPa, inclusive.

11. The display module according to claim 1, wherein
a transmittance of the transparent support layer is greater than or equal to 95%.

12. The display module according to claim 1, wherein
a material of the transparent support layer includes at least one of inorganic glass, thermoplastic rubber, colorless polyimide or organic glass.

13. The display module according to claim 1, further comprising:
a protective cover plate located on a side of the mirror structure layer away from the transparent support layer; and
a third adhesive layer located between the protective cover plate and the mirror structure layer, wherein
a material of the protective cover plate includes at least one of inorganic glass, thermoplastic rubber, colorless polyimide or organic glass.

14. The display module according to claim 1, further comprising:
a hardened coating disposed on a surface of the mirror structure layer away from the transparent support layer.

15. The display module according to claim 1, further comprising:
a heat dissipation film located on a back surface of the flexible display panel, the back surface being a surface opposite to the display surface, wherein
the heat dissipation film includes:
a fourth adhesive layer;
a buffer layer located on a side of the fourth adhesive layer away from the flexible display panel; and
a heat dissipation layer located on a side of the buffer layer away from the fourth adhesive layer; the heat dissipation layer including a stainless steel layer and/or a carbon fiber layer.

16. The display module according to claim 15, wherein the display module has a bendable area; and
at least a portion of the heat dissipation layer located in the bendable area is configured to have a hollow structure.

17. The display module according to claim 16, wherein the display module includes a scrollable display module or a foldable display module.

18. The display module according to claim 1, wherein the mirror structure layer includes at least one mirror orientation layer; and a direction of a transmission axis of the at least one mirror orientation layer is perpendicular to a direction of an absorption axis of the polarizer.

19. The display module according to claim 1, wherein the mirror structure layer includes a metal reflective layer.

20. A display apparatus, comprising the display module according to claim 1.
